(19) United States
(12) Patent Application Publication
(10) Pub. No.: US 2025/0029913 A1
(43) Pub. Date: Jan. 23, 2025

(54) SEMICONDUCTOR PACKAGE AND METHOD FOR FABRICATING THE SAME

(71) Applicant: SAMSUNG ELECTRONICS CO., LTD., Suwon-si (KR)

(72) Inventors: Jaesic LEE, Suwon-si (KR); Youngbae Kim, Suwon-si (KR)

(73) Assignee: SAMSUNG ELECTRONICS CO., LTD., Suwon-si (KR)

(21) Appl. No.: 18/419,084

(22) Filed: Jan. 22, 2024

(30) Foreign Application Priority Data
Jul. 18, 2023 (KR) 10-2023-0092989

(51) Int. Cl. H01L 23/498; H01L 21/027; H01L 23/00

(52) U.S. Cl. CPC H01L 23/49838; H01L 21/0274; H01L 23/49822; H01L 24/05; H01L 24/13; H01L 2224/05005; H01L 2224/05022; H01L 2224/13009; H01L 2224/13023; H01L 2924/01013; H01L 2924/01029; H01L 2924/049; H01L 2924/182

(57) ABSTRACT

A semiconductor package includes: a first semiconductor chip including a first semiconductor layer, and a first connection pad and a first insulation layer that are provided on a surface of the first semiconductor layer extending in a first direction; and a second semiconductor chip including a second semiconductor layer, and a second connection pad and a second insulation layer that are provided on a surface of the second semiconductor layer. The first connection pad directly contacts the second connection pad and is provided on the second connection pad in a second direction that is perpendicular to the first direction. The first insulation layer directly contacts the second insulation layer, the first insulation layer is provided on the second insulation layer in the second direction. A width of the second connection pad in the first direction is smaller than a width of the first connection pad in the first direction.

### CROSS-REFERENCE TO RELATED APPLICATION

This application claims priority to Korean Patent Application No. 10-2023-0092989, filed in the Korean Intellectual Property Office on Jul. 18, 2023, the disclosure of which is incorporated by reference herein in its entirety.

### BACKGROUND

### 1. Field

The present disclosure relates generally to a semiconductor package and a manufacturing method thereof.

### 2. Description of Related Art

When bonding a plurality of semiconductor chips, or bonding a semiconductor chip and a substrate, in a semiconductor package process, a process for directly connecting pads to each other without solder balls or solder bumps has been developed as a pitch between bonding pads narrows.

Hybrid bonding is to bond a plurality of semiconductor chips, or a semiconductor chip and a substrate, using the property of combining the same materials, and an input/output (I/O) with a fine pitch may be formed by the hybrid bonding.

In the hybrid bonding process, because pads have to contact with pads, and insulation layers have to contact with insulation layers, to form a bonding interface, it may be important to accurately align the bonding surfaces of the plurality of semiconductor chips (or substrates).

### SUMMARY

One or more example embodiments provide a semiconductor package including a structure that can improve reliability of a bonding process, and a manufacturing method thereof. In particular, according to one or more example embodiments, a connection pad of an upper semiconductor chip and a connection pad of a lower semiconductor chip may be different from each other in size, thereby assuring an align margin during hybrid bonding between both semiconductor chips, and accordingly, the reliability of the bonding process may be improved.

According to an aspect of an example embodiment, a semiconductor package includes: a first semiconductor chip comprising: a first semiconductor layer; a first connection pad provided on a surface of the first semiconductor layer, and a first insulation layer provided on the surface of the first semiconductor layer, the surface of the first semiconductor layer extending in a first direction; and a second semiconductor chip comprising: a second semiconductor layer; a second connection pad provided on a surface of the second semiconductor layer; and a second insulation layer provided on the surface of the second semiconductor layer, wherein the first connection pad directly contacts the second connection pad, wherein the first connection pad is provided on the second connection pad in a second direction that is perpendicular to the first direction, wherein the first insulation layer directly contacts the second insulation layer, wherein the first insulation layer is provided on the second insulation layer in the second direction, and wherein a width of the second connection pad in the first direction is smaller than a width of the first connection pad in the first direction.

According to an aspect of an example embodiment, a semiconductor package includes: an interposer; a logic die provided on the interposer; and a high bandwidth memory provided on the interposer, wherein the high bandwidth memory comprises: a buffer die; a first semiconductor chip that is provided on the buffer die, the first semiconductor chip comprising: a first semiconductor layer; a first connection pad provided on a surface of the first semiconductor layer; and a first insulation layer provided on the surface of the first semiconductor layer, the surface of the first semiconductor layer extending in a first direction; and a second semiconductor chip comprising: a second semiconductor layer; a second connection pad provided on a surface of the second semiconductor layer; and a second insulation layer provided on the surface of the second semiconductor layer, wherein the first connection pad directly contacts the second connection pad, wherein the first connection pad is provided on the second connection pad in a second direction that is perpendicular to the first direction, wherein the first insulation layer directly contacts the second insulation layer, wherein the first insulation layer is provided on the second insulation layer in the second direction, and wherein the semiconductor package comprises a molding member that is provided on the buffer die and that molds the first semiconductor chip and the second semiconductor chip.

According to an aspect of an example embodiment, a method of manufacturing a semiconductor package, the method comprising: forming a first semiconductor chip comprising: a first semiconductor layer; a first connection pad provided on a surface of the first semiconductor layer, and a first insulation layer provided on the surface of the first semiconductor layer, the surface of the first semiconductor layer extending in a first direction; forming a second semiconductor chip comprising: a second semiconductor layer; a second connection pad provided on a surface of the second semiconductor layer, a second insulation layer provided on the surface of the second semiconductor layer; and bonding the first semiconductor chip and the second semiconductor chip such that the first connection pad and the second connection pad directly contact and the first insulation layer and the second insulation layer directly contact, wherein a width of the second connection pad in the first direction is smaller than a width of the first connection pad in the first direction.

### BRIEF DESCRIPTION OF THE DRAWINGS

The above and other aspects and features will be more apparent from the following description of one or more example embodiments taken in conjunction with the accompanying drawings, in which:

FIG. 1 shows a semiconductor package according to one or more example embodiments;

FIG. 2A is an enlarged cross-sectional view of the bonding portion of the semiconductor package of FIG. 1 according to one or more example embodiments;

FIG. 2B is an enlarged top plan view of the bonding portion of the semiconductor package of FIG. 1 according to one or more example embodiments;

FIGS. 3A, 3B, 3C, 3D, 3E, and 3F illustrate a method for forming the bonding portion of the upper semiconductor chip in one or more example embodiments;

FIGS. 4A, 4B, 4C, 4D, 4E, 4F, 4G and 4H illustrate a method for bonding portion of the lower semiconductor chip in one or more example embodiments;

FIG. 5A and FIG. 5B illustrate a method for bonding an upper structure and a lower structure in one or more example embodiments;

FIG. 6 illustrates a bonding portion of a semiconductor package according to one or more example embodiments;

FIG. 7 illustrates a bonding portion of a semiconductor package according to one or more example embodiments;

FIG. 8 illustrates a bonding portion of a semiconductor package according to one or more example embodiments;

FIG. 9 illustrates a bonding portion of a semiconductor package according to one or more example embodiments;

FIG. 10 illustrates a semiconductor package according to one or more example embodiments;

FIG. 11 is a cross-sectional view of a 2.5D semiconductor package including a bonding structure according to one or more example embodiments; and

FIG. 12 is a cross-sectional view of a 3D semiconductor package including a bonding structure according to one or more example embodiments.

### DETAILED DESCRIPTION

Hereinafter, example embodiments will be described in detail with reference to accompanying drawings. The present disclosure may be implemented in a number of different forms and is not limited to the example embodiments described herein.

In the following description, parts irrelevant to the description have been omitted, and the same reference numerals are used for the same or similar constituent elements throughout the specification.

In addition, the size and thickness of each component shown in the drawings are arbitrarily represented for the convenience of description, and thus embodiments of the disclosure are not necessarily limited to the drawings. In the drawings, the thickness of layers, films, panels, regions, etc., are exaggerated for clarity. In addition, in the drawings, for convenience of explanation, the thickness of some layers and regions are exaggerated.

It will be apparent that when an element such as a layer, film, region, or substrate is referred to as being “on” another element, the element can be directly on the other element or intervening elements may also be present. In contrast, when an element is referred to as being “directly on” another element, there are no intervening elements present. Further, throughout the specification, the word “on” a target element may mean positioned above or below the target element, and may not necessarily be understood to mean positioned “at an upper side” based on an opposite to a gravity direction.

In addition, unless explicitly described to the contrary, the word “comprise”, and variations such as “comprises” or “comprising” may imply the inclusion of stated elements but not the exclusion of any other elements.

Further, throughout the specification, the phrase “on a plane” may mean viewing a target portion from the top, and the phrase “on a cross-section” may mean viewing a cross-section formed by vertically cutting a target portion from the side.

Hereinafter, a semiconductor package according to example embodiments will be described with reference to the drawings.

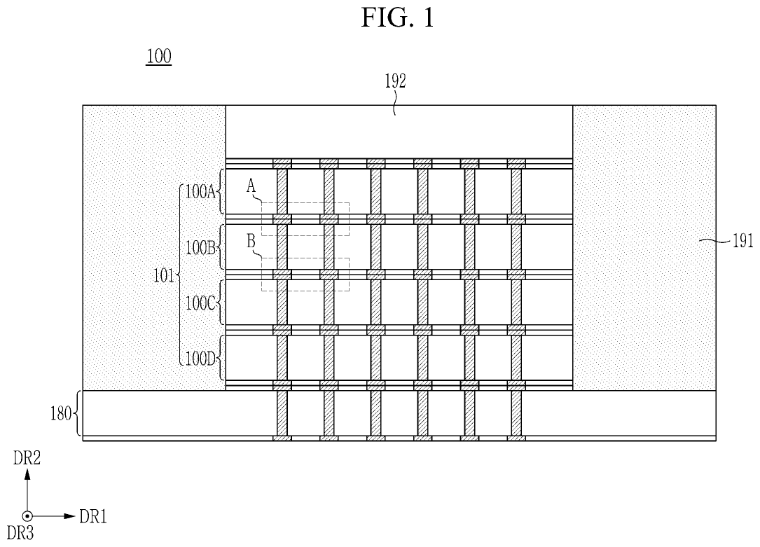

FIG. 1 shows a semiconductor package according to one or more example embodiments.

Referring to FIG. 1, according to one or more example embodiments, a semiconductor package 100 may include a semiconductor chip stacking structure 101, a bottom die 180, molding member 191, and a dummy silicon layer 192.

The semiconductor chip stacking structure 101 may have a structure in which a plurality of semiconductor chips 100A, 100B, 100C, and 100D are stacked in one direction (e.g., a second direction DR2). The semiconductor chip stacking structure 101 may be disposed on the bottom die 180. In one or more example embodiments, the bottom die 180 may have a larger width than the semiconductor chip stacking structure 101 in a first direction DR1.

In one or more example embodiments, the semiconductor package 100 may include a high bandwidth memory (HBM). According to one or more example embodiments, each of the plurality of semiconductor chips 100A, 100B, 100C, and 100D stacked in the semiconductor chip stacking structure 101 may be a memory chip (e.g., DRAM), and the bottom die 180 may be a buffer die. In the following one or more example embodiments, it will be exemplarily described that the semiconductor package 100 includes the HBM, but one or more example embodiments are not limited to the HBM.

The semiconductor chip stacking structure 101 and the bottom die 180 may be bonded by hybrid bonding. Each of the semiconductor chips 100A, 100B, 100C, and 100D included in the semiconductor chip stacking structure 101 may be bonded to each other by hybrid bonding. Hybrid bonding may be performed by a bonding portion included in each of the semiconductor chips 100A, 100B, 100C, and 100D or the bottom die 180. The bonding portion may be a portion where each of the semiconductor chips contacts each other in the case that the plurality of semiconductor chips 100A, 100B, 100C, and 100D are stacked and connected to each other. Alternatively, the bonding portion may be a portion where the semiconductor chip and the bottom die 180 contact each other when any one of the plurality of semiconductor chips 100A, 100B, 100C, and 100D and the bottom die 180 are connected to each other.

Hybrid bonding is a method of fusing the same materials of two devices by using the bonding properties of the same materials to bond two devices. For example, in the bonding portion, hybrid bonding may mean that two devices are bonded to each other through metal-metal bonding and non-metal-non-metal bonding. According to hybrid bonding, an I/O with a fine pitch may be formed. Specifically, when two semiconductor chips are bonded to each other, a bonding portion of each semiconductor chip may include one or more metal pads and an insulation layer adjacent to the metal pad. According to one or more example embodiments, in the bonding portion, a metal pad may be bonded between metal pads, and an insulation layer may be bonded between insulation layers.

In one or more example embodiments, an upper semiconductor chip and a lower semiconductor chip may each include metal pads with different widths. In one or more example embodiments, the upper semiconductor chip and the lower semiconductor chip may each include insulation layers having different widths. In one or more example embodiments, the contact surface of the metal pad and the contact surface of the insulation layer may be positioned in different layers.

The molding member 191 may be disposed on the bottom die 180 and may mold the semiconductor chip stacking structure 101. The molding member 191 may serve to protect and insulate the semiconductor chip stacking structure 101. In one or more example embodiments, the molding member 191 may comprise a thermosetting resin such as epoxy resin. In one or more example embodiments, the molding member 191 may comprise an epoxy molding compound (EMC). In one or more example embodiments, the molding process with the molding member 191 may include a compression molding or transfer molding process.

The dummy silicon layer 192 may be configured to radiate heat generated within the high bandwidth memory to the outside. The dummy silicon layer 192 may include crystalline silicon. The thermal conductivity of silicon may have a value greater than that of molding member 190. Heat generated in the high bandwidth memory may be effectively dissipated by the dummy silicon layer 192 comprising silicon.

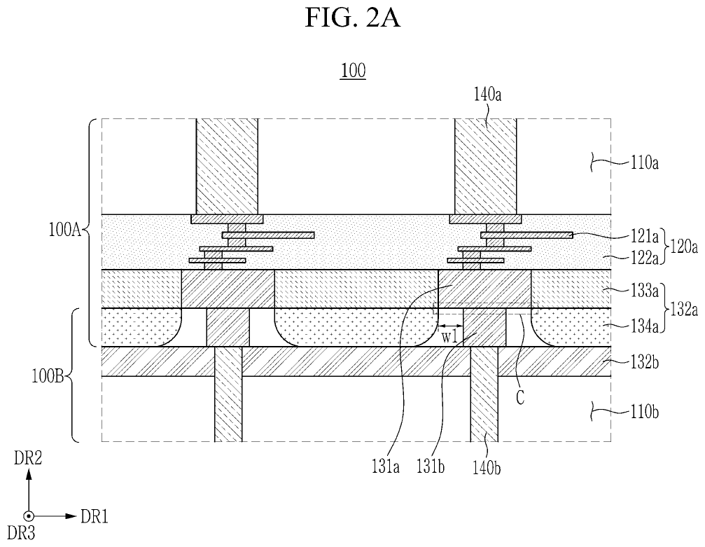

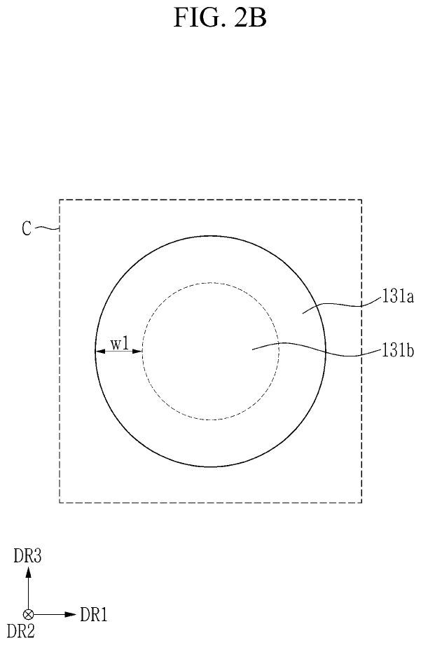

FIG. 2A is an enlarged cross-sectional view of the bonding portion of the semiconductor package of FIG. 1.

For example, FIG. 2A may show a bonding portion of a portion where a first semiconductor chip 100A and a second semiconductor chip 100B are in contact in the semiconductor package of FIG. 1. For example, FIG. 2A may be an enlarged view of the portion A in the semiconductor package 100 of FIG. 1.

The first semiconductor chip 100A may be connected to the second semiconductor chip 100B using a flip chip method. For example, in FIG. 2A, the bonding portion may be formed by bonding an upper surface of the first semiconductor chip 100A and a bottom surface of the second semiconductor chip 100B.

Referring to FIG. 2A, according to one or more example embodiments, a bonding portion of the first semiconductor chip 100A may include a first semiconductor layer 110a, an interconnection structure 120a, a first connection pad 131a, a first insulation layer 132a, and a first through electrode 140a. The first insulation layer 132a may include a lower insulation layer 133a and an upper insulation layer 134a.

The first semiconductor layer 110a may include a compound semiconductor such as, for example, a semiconductor device such as silicon (Si) or germanium (Ge), silicon carbide (SiC), gallium arsenide (GaAs), indium arsenide (InAs), or indium phosphide (InP). The first semiconductor layer 110a may have a silicon-on insulator (SOI) structure. The first semiconductor layer 110a may include an active region, for example, an impurity doped well, or an impurity doped structure. The first semiconductor layer 110a may include various device isolation structures such as a shallow trench isolation (STI) structure. According to one or more example embodiments, the first semiconductor layer 110a may include one or more separate semiconductor device (e.g., a transistor) at a position adjacent to the interconnection structure 120a.

The interconnection structure 120a may be disposed on the first semiconductor layer 110a. The interconnection structure 120a may include a wiring layer 121a and an wiring insulation layer 122a surrounding the wiring layer 121a. The wiring layer 121a may include a multi-layer structure including wiring patterns and vias. According to one or more example embodiments, the wiring layer 121a may further include a thick top metal (TTM). The wiring patterns and the vias included in the wiring layer 121a may include a metal material. For example, the wiring patterns and the vias may include copper (Cu), aluminum (AI), silver (Ag), tin (Sn), gold (Au), nickel (Ni), lead (Pb), titanium (Ti) or at least two or more alloys thereof. The wiring insulation layer 122a may include an insulating material. For example, the wiring insulation layer 122a may include an insulating material such as silicon oxide, silicon nitride, insulating polymer, or a combination thereof. The wiring layer 121a may connect individual semiconductor devices included in a first through electrode 140a and a first semiconductor layer 110a with a first connection pad 131a disposed on the upper surface of the first semiconductor chip 100A through the wiring patterns and vias.

A first connection pad 131a and a lower insulation layer 133a surrounding the side of the first connection pad 131a may be disposed on the interconnection structure 120a. The first connection pad 131a may directly contact the second connection pad 131b included in the second semiconductor chip 100B in the vertical direction (e.g., second direction DR2). The lower insulation layer 133a may prevent the plurality of first connection pads 131a disposed on the interconnection structure 120a from contacting each other and may insulate the plurality of first connection pads 131a from each other. The lower insulation layer 133a may include an insulating material. For example, the lower insulation layer 133a may include an insulating material such as silicon oxide, silicon nitride, insulating polymer, or a combination thereof.

The upper insulation layer 134a may be disposed on the lower insulation layer 133a. In one or more example embodiments, an upper surface (i.e., a surface contacting the second insulation layer 132b) of the upper insulation layer 134a may be formed at a layer of a different height from an upper surface of the first connection pad 131a (i.e., a surface in contact with the second connection pad 131b). That is, the upper insulation layer 134a may be protruded in the opposite direction of the second direction DR2 based on the upper surface of the lower insulation layer 133a and/or first connection pad 131a. That is, the upper surface of the first connection pad 131a may be disposed in a concave portion in the second direction DR2 from the upper surface of the upper insulation layer 134a. In one or more example embodiments, a width of the upper insulation layer 134a in the horizontal direction (e.g., first direction DR1) may gradually decrease as it moves toward the vertical direction (e.g., the opposite direction of the second direction DR2). In one or more example embodiments, an edge of a portion adjacent to the second connection pad 131b of the upper insulation layer 134a may have a round shape. In one or more example embodiments, the upper insulation layer 134a may be formed in a subsequent process after the first connection pad 131a and the lower insulation layer 133a are formed. The upper insulation layer 134a may include an insulating material such as silicon oxide, silicon nitride, insulating polymer, or a combination thereof. The upper insulation layer 134a may directly contact the second insulation layer 132b included in the second semiconductor chip 100B in the vertical direction.

The first through electrode 140a may penetrate the first semiconductor layer 110a in the vertical direction (e.g., second direction DR2). The through electrodes 140a and 140b may be formed by drilling thousands of fine holes vertically penetrating each of the semiconductor chip 100A and 100B, filling the holes with conductive material, and connecting them to electrodes. Holes of the through electrodes 140a and 140b may be formed by deep etching. In one or more example embodiments, the holes of the through electrodes 140a and 140b may be formed by laser. The through electrodes 140a and 140b may include a conductive plug and a barrier layer surrounding the conductive plug. In one or more example embodiments, the holes of the through electrodes 140a and 140b may be filled by electrolytic plating. In one or more example embodiments, the conductive plugs of the through electrodes 140a and 140b may include at least one of tungsten (W), aluminum (AI), copper (Cu), and alloys thereof. The barrier layer may contain at least one of the following metal compounds: titanium nitride (TiN), tantalum nitride (TaN), or tungsten nitride (WN). Referring to FIG. 2A, according to one or more example embodiments, the first through electrode 140a may electrically connect the first connection pad 131a disposed on the upper surface of the first semiconductor layer 110a and a connection pad disposed on a lower surface of the first semiconductor layer 110a.

Referring to FIG. 2A, according to one or more example embodiments, the bonding portion of the second semiconductor chip 100B may include a second semiconductor layer 110b, a second connection pad 131b, a second insulation layer 132b, and a second through electrode 140b.

The second semiconductor layer 110b may include, for example, a semiconductor device such as silicon (Si) or germanium (Ge), or compound semiconductors such as silicon carbide (SiC), gallium arsenide (GaAs), indium arsenide (InAs), or indium phosphide (InP). The second semiconductor layer 110b may have a SOI structure. The second semiconductor layer 110b may include an active region, for example, an impurity doped well, or an impurity doped structure. The second semiconductor layer 110b may include various device isolation structures such as an STI structure. In FIG. 2A, the second semiconductor layer 110b may be a portion adjacent to the lower surface of the second semiconductor chip 100B.

The second insulation layer 132b may be disposed on the second semiconductor layer 110b. The second insulation layer 132b may include an insulating material. For example, the second insulation layer 132b may include an insulating material such as silicon oxide, silicon nitride, insulating polymer, or a combination thereof. The second insulation layer 132b may surround a portion of the sidewall of the second through electrode 140b that penetrates the second semiconductor layer 110b in the vertical direction. The second insulation layer 132b may directly contact the upper insulation layer 134a of the first semiconductor chip 100A in the vertical direction (e.g., second direction DR2).

The second connection pad 131b may be disposed on the second semiconductor layer 110b. The second connection pad 131b may directly contact the first connection pad 131a included in the first semiconductor chip 100A in the vertical direction (e.g., second direction DR2). In one or more example embodiments, a width of the second connection pad 131b in the horizontal direction (e.g., first direction DR1) may be smaller than a width of the first connection pad 131a in the horizontal direction. A lower surface of the second connection pad 131b (a surface in contact with the first connection pad 131a) may be formed at a layer of a different height than a lower surface of the second insulation layer 132b (a surface in contact with the upper insulation layer 134a). That is, the second connection pad 131b may be protruded in the second direction DR2 based on an upper surface of the second insulation layer 132b. Accordingly, as shown in FIG. 2A, when the first semiconductor chip 100A and the second semiconductor chip 100B are bonded, the second connection pad 131b of the second semiconductor chip 100B and the upper insulation layer 134a of the first semiconductor chip 100A may be disposed on the same layer, and an empty space may be positioned between a side surface of the second connection pad 131b and a side surface of the upper insulation layer 134a.

The second through electrode 140b may penetrate the second semiconductor layer 110b in the vertical direction (e.g., second direction DR2). Referring to FIG. 2A, according to one or more example embodiments, the second through electrode 140b may electrically connect the second connection pad 131b disposed on the lower surface of the second semiconductor layer 110b with a connection pad disposed on an upper surface of the second semiconductor layer 110b. In one or more example embodiments, a width of the second through electrode 140b in the first direction DR1 may be different from a width of the first through electrode 140a in the first direction DR1. For example, the width of the second through electrode 140b in the first direction DR1 may be smaller than the width of the first through electrode 140a in the first direction DR1.

In one or more example embodiments, the first connection pad 131a and the second connection pad 131b may include the same metal material. For example, the first connection pad 131a and the second connection pad 131b may include copper (Cu). Referring to FIG. 2A, according to one or more example embodiments, the first connection pad 131a and the second connection pad 131b may be bonded by metal-metal bonding. That is, bonding may be achieved between the same metal materials at the interface between the first connection pad 131a and the second connection pad 131b, and, accordingly, the interface between the first connection pad 131a and the second connection pad 131b may not be discernable. As a result, the first connection pad 131a and the second connection pad 131b may be integrated.

In one or more example embodiments, the first insulation layer 132a and the second insulation layer 132b may include the same insulating material. For example, the first insulation layer 132a and the second insulation layer 132b may include silicon oxide, silicon nitride, and TEOS forming oxide. The first insulation layer 132a and the second insulation layer 132b may be directly bonded by non-metal-non-metal bonding. That is, at the interface between the first insulation layer 132a and the second insulation layer 132b, covalent bonds may be formed between the same insulating materials, and accordingly, the interface between the first insulation layer 132a and the second insulation layer 132b may not be discernable. That is, the first insulation layer 132a and the second insulation layer 132b may be integrated.

FIG. 2B is an enlarged top plan view of the bonding portion of the semiconductor package of FIG. 1.

Specifically, FIG. 2B is an enlarged top plan view of the portion C of FIG. 2A. It is illustrated in FIG. 2B that the first connection pad 131a and the second connection pad 131b have circular-shaped cross-sections, but one or more example embodiments are not limited thereto, and the shape of the connection pads may be formed in various shapes, such as a square or a triangle.

Referring to FIG. 2A and FIG. 2B, according to one or more example embodiments, a width of the first connection pad 131a and a width of the second connection pad 131b are different from each other in the first direction DR1, and a width of the upper insulation layer 134a in the first direction and a width of the second insulation layer 132b in the first direction may be different from each other. For example, the width of the first connection pad 131a may be larger than the width of the second connection pad 131b, and the width of the upper insulation layer 134a in the first direction may be smaller than the width of the second insulation layer 132b in the first direction. Accordingly, an empty space may be formed between a side surface of the second connection pad 131b and a side surface of the upper insulation layer 134a.

When the first semiconductor chip 100A and the second semiconductor chip 100B are bonded by hybrid bonding in the second direction DR2, a metal had to be bonded with a metal and an insulating material has to be bonded with an insulating material, and therefore it may be important to accurately align the first semiconductor chip 100A and the second semiconductor chip 100B vertically. According to one or more example embodiments, an edge of the first connection pad 131a and an edge of the second connection pad 131b may be separated by a first distance w1. According to one or more example embodiments, the width of the first connection pad 131a in the first direction DR1 is about twice the first distance w1 than the width of the second connection pad 131b in the first direction, and therefore, in the process of bonding the first semiconductor chip 100A and the second semiconductor chip 100B, an alignment margin of approximately twice the first distance w1 can be secured.

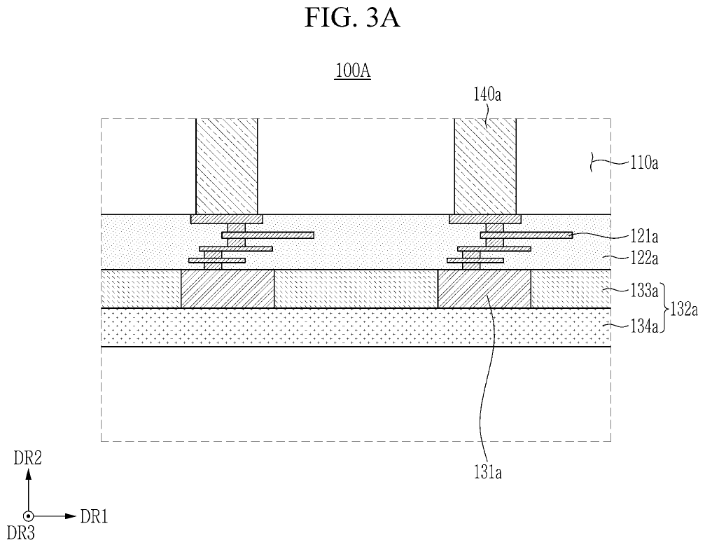

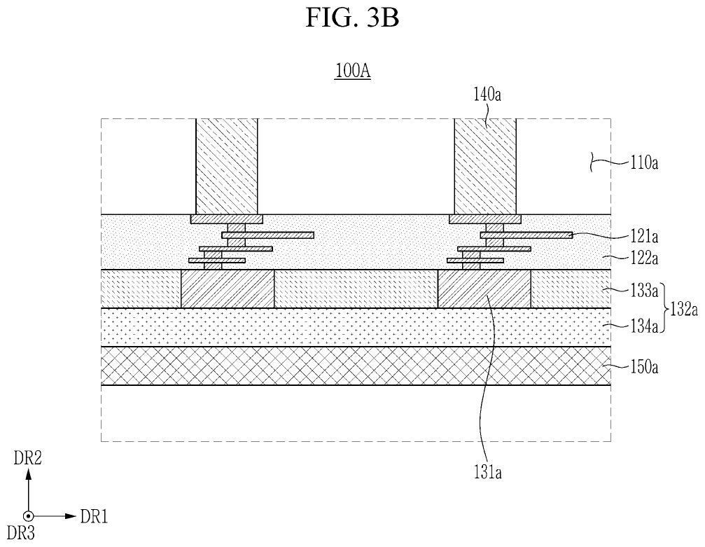

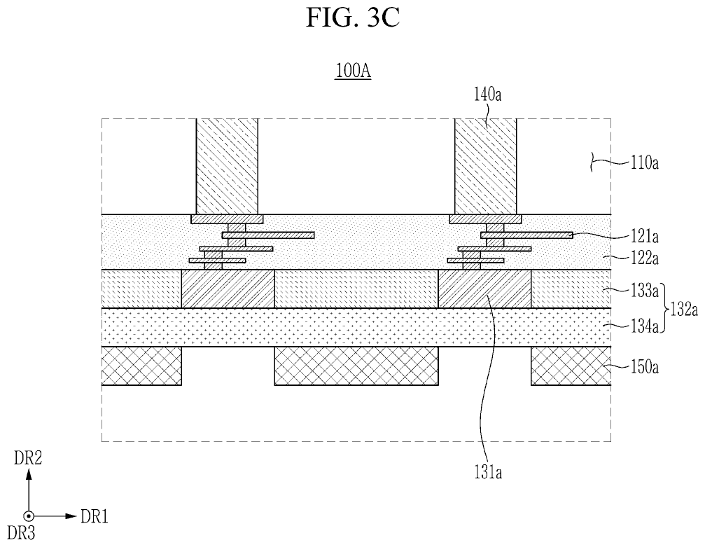

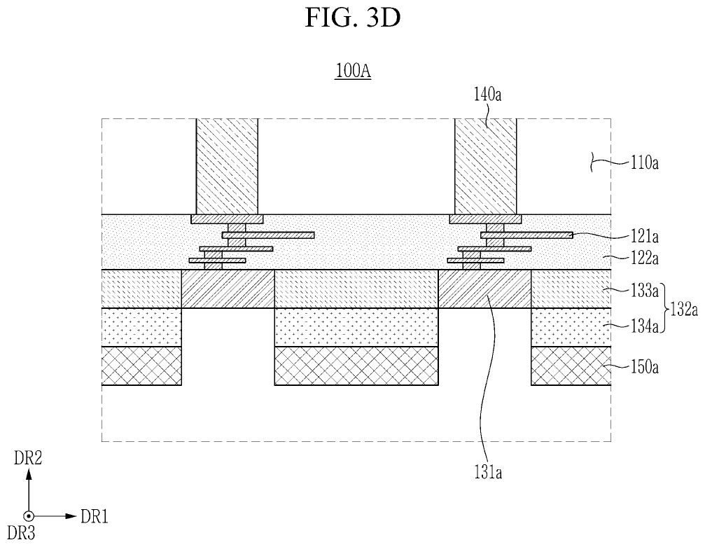

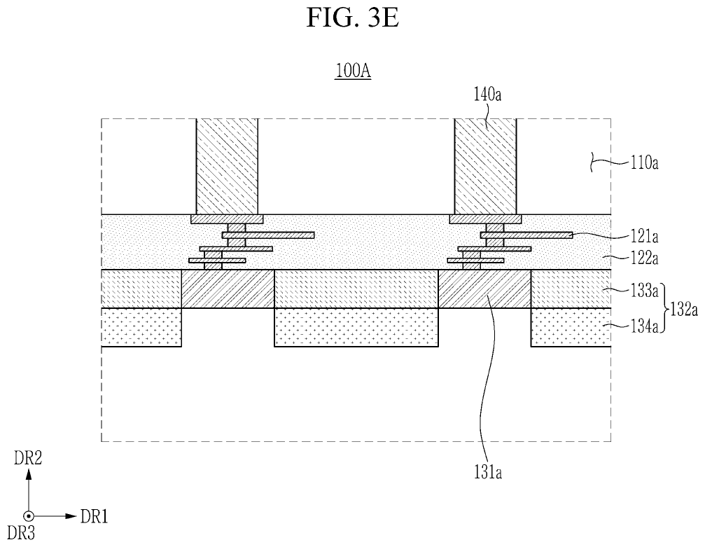

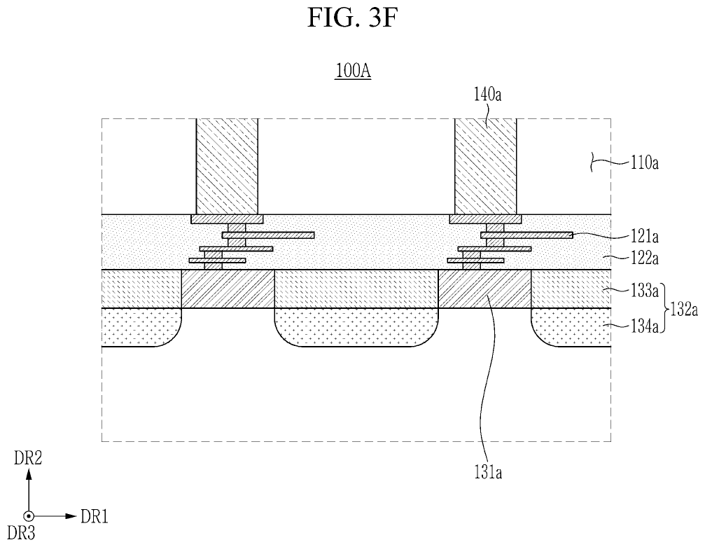

FIGS. 3A, 3B, 3C, 3D, 3E, and 3F illustrate a method for forming the bonding portion of the upper semiconductor chip in one or more example embodiments. For example, the upper semiconductor chip may be the first semiconductor chip 100A in FIG. 1 and FIG. 2A.

Referring to FIG. 3A, according to one or more example embodiments, the upper insulation layer 134a may be disposed on the first connection pad 131a and the lower insulation layer 133a. According to one or more example embodiments, the upper insulation layer 134a may include the same material as the lower insulation layer 133a. The upper insulation layer 134a may be deposited on the first connection pad 131a and the lower insulation layer 133a by, for example, chemical vapor deposition.

Referring to FIG. 3B and FIG. 3C, according to one or more example embodiments, a photoresist film 150a may be provided on the upper insulation layer 134a. The photoresist film 150a may be coated on the upper insulation layer 134a by a spin coating method, or may be provided on the insulation layer 134a by a laminating method. After that, exposure, baking, and development processes may be performed to form an opening in the photoresist film 150a. The opening may expose one side of the upper insulation layer 134a. A width of the opening in the first direction DR1 may be substantially the same as the width of the first connection pad 131a in the first direction DR1. In one or more example embodiments, the area of the upper insulation layer 134a exposed by opening may be substantially the same as the area of the first connection pad 131a.

Referring to FIG. 3D, according to one or more example embodiments, a part of the upper insulation layer 134a may be removed by an etching process. For example, a portion of the upper surface of the upper insulation layer 134a, exposed by the opening, may be removed by the etching process. In one or more example embodiments, the upper insulation layer 134a may be removed by a dry etching process such as reactive ion etching (RIE) or inductively coupled plasma (ICP). In one or more example embodiments, the upper insulation layer 134a may also be removed by a wet etching process.

Referring to FIG. 3E, according to one or more example embodiments, after the portion of the upper surface of the upper insulation layer 134a, exposed by the opening is removed by the etching process, the photoresist film 150a provided on the upper insulation layer 134a may be removed by an ashing process.

Referring to FIG. 3F, according to one or more example embodiments, after the photoresist film 150a is provided, an edge of a portion of the upper insulation layer 134a, protruding in the opposite direction of the second direction DR2 may be etched to have a round shape. According to one or more example embodiments, the upper insulation layer 134a may be etched by a wet etching method. In the case of wet etching, an etching rate of a region including the edge portion may be faster than an etching rate of the remaining portion not including the edge portion. Accordingly, when the upper insulation layer 134a is wet-etched for a predetermined time period in an etching solution selected according to an insulation material included in the upper insulation layer 134a, the edge of the protruded portion of the upper insulation layer 134a may be etched to have a rounded shape. When the edge of the upper insulation layer 134a has a rounded shape, the phenomenon of defects occurring inside the insulation layer or pad adjacent to the bonding portion due to contact stress that may occur when two semiconductor chips are bonded can be improved.

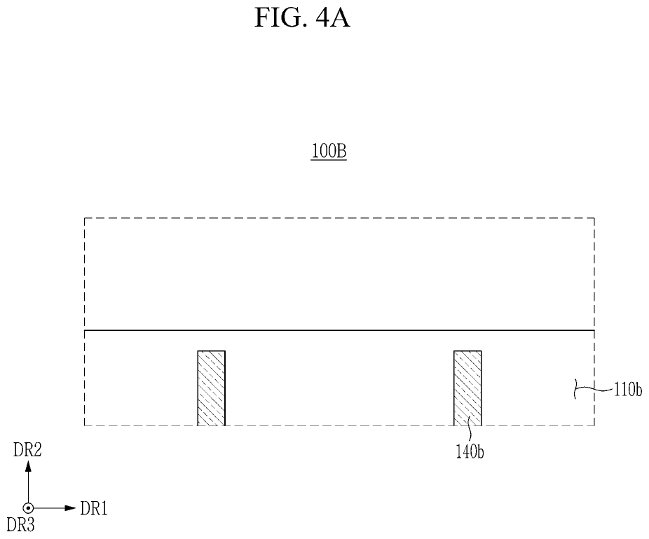

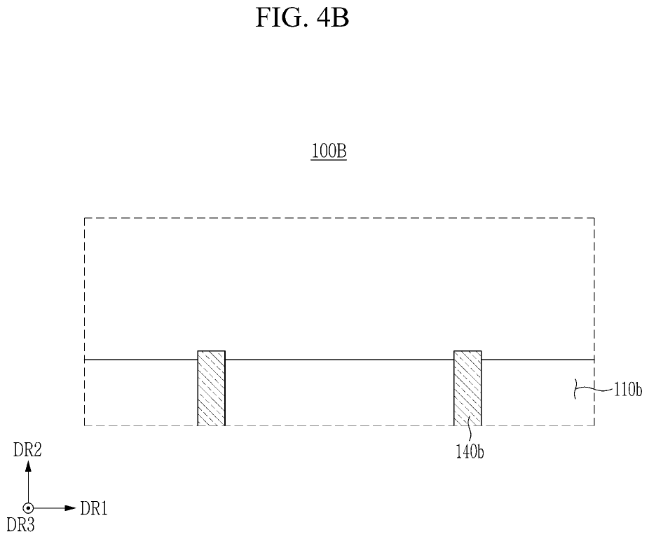

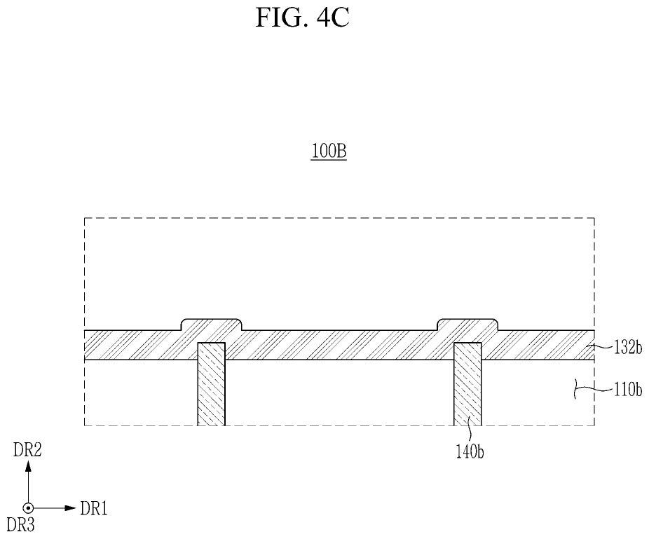

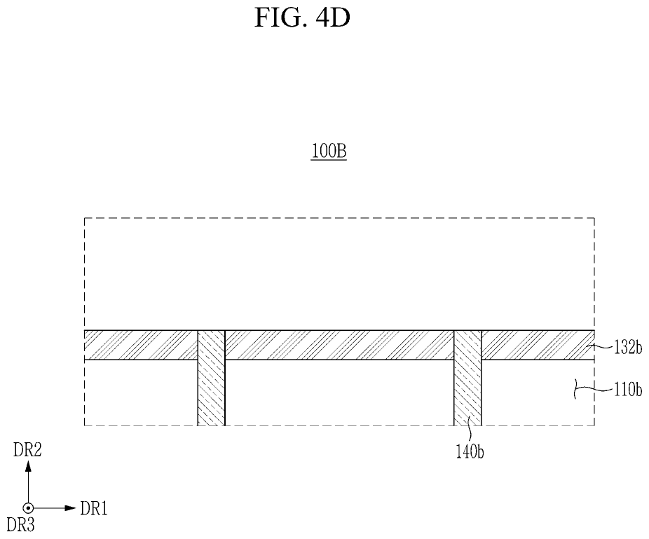

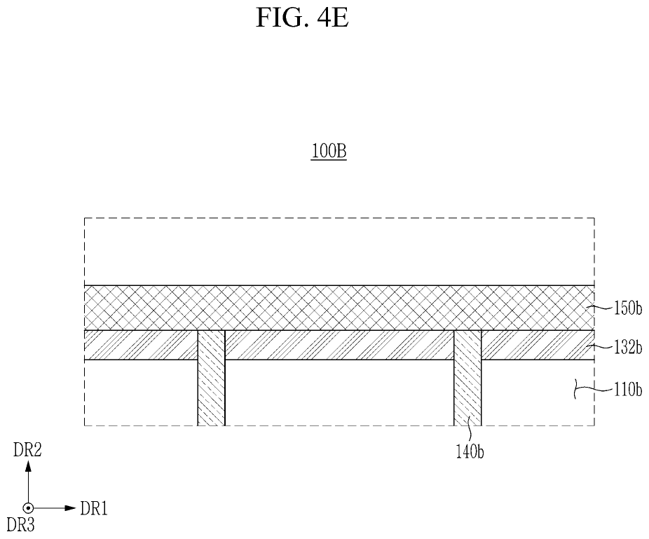

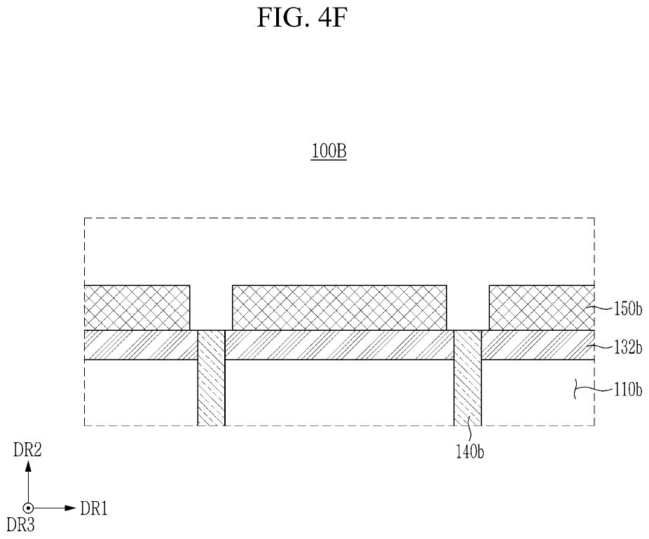

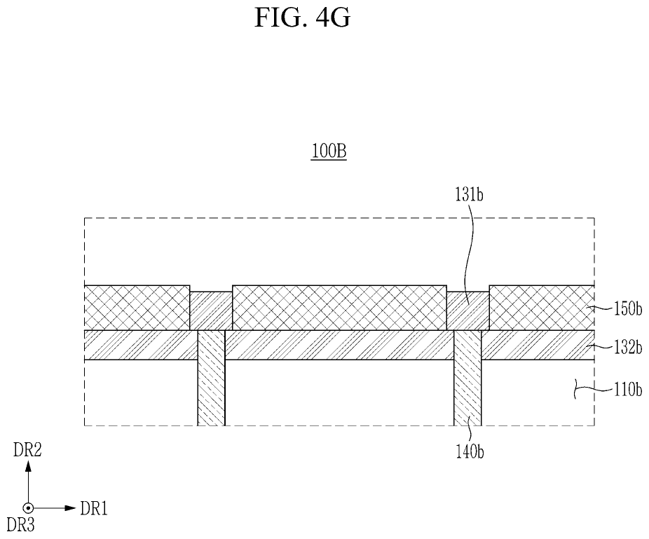

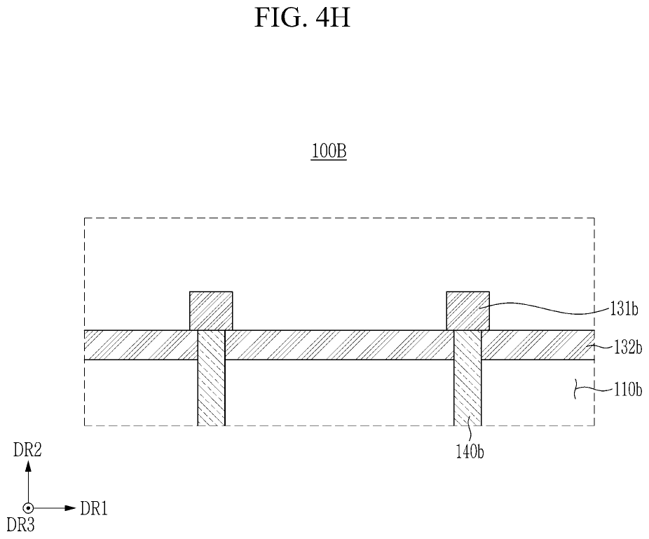

FIGS. 4A, 4B, 4C, 4D, 4E, 4F, 4G and 4H illustrate a method for bonding portion of the lower semiconductor chip in one or more example embodiments. For example, the lower semiconductor chip may be the second semiconductor chip 100B in FIG. 1 and FIG. 2A.

Referring to FIG. 4A and FIG. 4B, according to one or more example embodiments, one side (e.g., a rear surface) of the second semiconductor chip 100B is polished to reduce a thickness of the second semiconductor layer 110b. According to one or more example embodiments, one side of the second semiconductor layer 110b may be polished by a grinding, chemical mechanical polishing (CMP), or etch-back process, or a combination thereof. After one side of the second semiconductor layer 110b is polished, a portion of the second through electrode 140b may have a shape protruded in the second direction DR2.

Referring to FIG. 4C and FIG. 4D, according to one or more example embodiments, after the polishing process is finished, the second insulation layer 132b is formed on the second semiconductor chip 100B, and then the second insulation layer 132b may be polished such that the second through electrode 140b is exposed on the second insulation layer 132b. The second insulation layer 132b may include the same insulating material as the upper insulation layer 134a of the first semiconductor chip 100A. For example, the second insulation layer 132b may include silicon oxide or silicon nitride.

Referring to FIGS. 4E, 4F, 4G, and 4H, according to one or more example embodiments, the second connection pad 131b may be formed in the region of the second through electrode 140b, exposed on the second insulation layer 132b. Specifically, the photoresist film 150b is provided on the second insulation layer 132b and patterned to form an operation exposing an upper portion of the second through electrode 140b. According to one or more example embodiments, the area of the opening formed in the photoresist film 150b may be larger than the area of the second through electrode 140b exposed on the second insulation layer 132b, and may be smaller than the area of a surface facing second direction DR2 of the first connection pad 131a. The second connection pad 131b may be formed in the opening formed in the photoresist film 150b. The second connection pad 131b may be formed on the second insulation layer 132b by an electroplating method. However, the method for forming the second connection pad 131b is not limited to the present one or more example embodiments, and the second connection pad 131b may also be formed through an electroless plating or PVD (e.g., sputtering) process. After then second connection pad 131b is formed on the second insulation layer 132b, the photoresist film 150b may be removed by an ashing process.

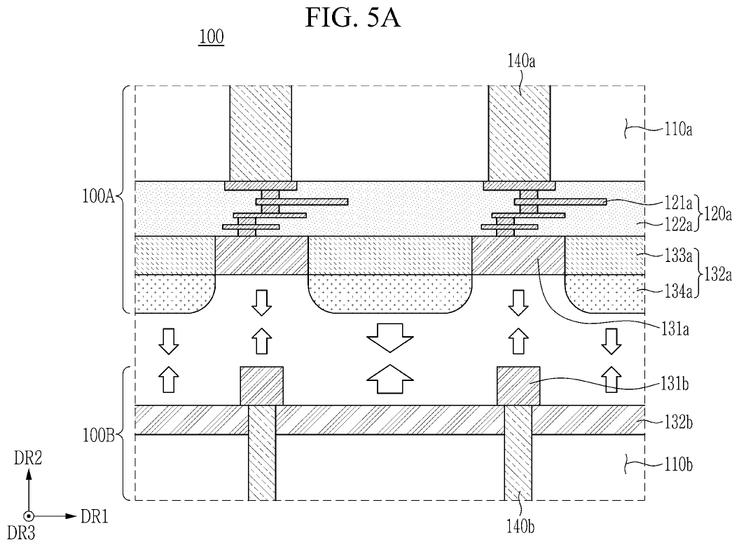

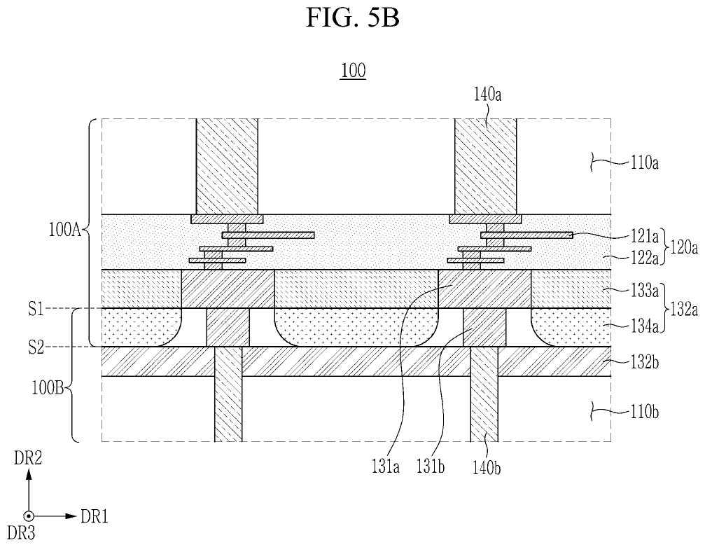

FIG. 5A and FIG. 5B illustrate a method for bonding an upper structure and a lower structure in one or more example embodiments.

Referring to FIG. 5A and FIG. 5B, according to one or more example embodiments, the first connection pad 131a and the first insulation layer 132a are formed on one side (e.g., the front side) of the first semiconductor chip 100A, the second connection pad 131b and the second insulation layer 132b are formed on one side (e.g., the rear side) of the second semiconductor chip 100B, and then one side of the first semiconductor chip 100A and one side of the second semiconductor chip 100B may be bonded to each other. For example, the first semiconductor chip 100A and the second semiconductor chip 100B may be aligned in the vertical direction (e.g., second direction DR2) before the bonding. According to one or more example embodiments, the first semiconductor chip 100A and the second semiconductor chip 100B may be aligned such that the first connection pad 131a and the second connection pad 131b face each other and the first insulation layer 132a and the second insulation layer 132b face each other. As previously described with reference to FIG. 2B, in the process of bonding the first semiconductor chip 100A and the second semiconductor chip 100B, an align margin of approximately twice the first distance w1 is secured, and thus it may be easy to align the first semiconductor chip 100A and the second semiconductor chip 100B. After the align process, the first semiconductor chip 100A and the second semiconductor chip 100B may be bonded by moving the two semiconductor chips in the vertical direction. According to one or more example embodiments, the first semiconductor chip 100A and the second semiconductor chip 100B may move until the first connection pad 131a and the second connection pad 131b contact each other and the first insulation layer 132a and the second insulation layer 132b contact each other. In one or more example embodiments, a layer where the first connection pad 131a and the second connection pad 131b are in contact may be different from a layer where the first insulation layer 132a and the second insulation layer 132b are in contact. Referring to FIG. 5B, according to one or more example embodiments, the first connection pad 131a and the second connection pad 131b may contact each other at an interface S1, and the first insulation layer 132a and the second insulation layer 132b may contact each other at an interface S2 at a different height from the interface S1. The phenomenon of cracks occurring on the surface where the connection pad and insulation layers contact each other can be improved by separating the interface where the connection pads contact each other and the interface where the insulation layers contact each other.

After the first semiconductor chip 100A and the second semiconductor chip 100B are bonded, the bonding portion can be heated to a predetermined temperature. According to one or more example embodiments, the bonding portion may be heated at 160° C. to 220° C. As the bonding portion is heated during the bonding process, the volume of the connection pads may increase, and as a result, mutual stress may occur between the connection pad and the insulation layer, which may cause defects inside the connection pad or the insulation layer. In one or more example embodiments, the phenomenon of defects occurring as described above inside the connection pad or insulation layer in the junction process may be improved by including an empty space between the pad and the insulation layer.

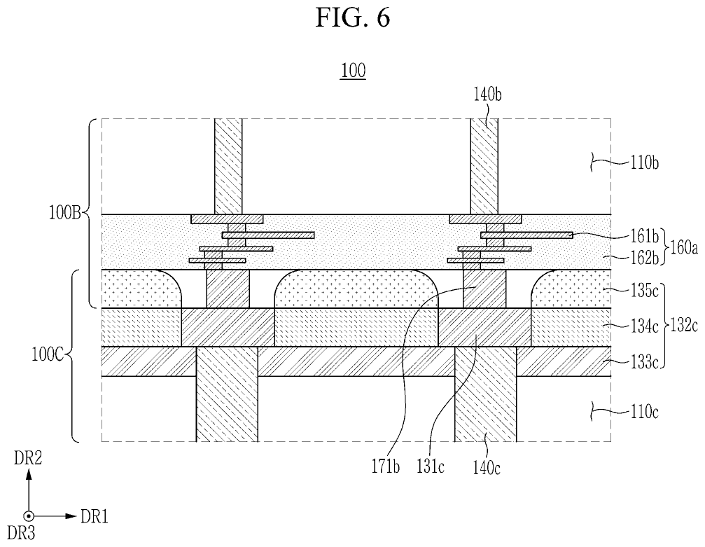

FIG. 6 illustrates a bonding portion of a semiconductor package according to one or more example embodiments.

For example, FIG. 2A may show the bonding portion of the portion where the second semiconductor chip 100B and the third semiconductor chip 100C contact each other in the semiconductor package of FIG. 1. For example, FIG. 6 may be an enlarged view of the portion B in the semiconductor package 100 of FIG. 1. That is, FIG. 2A shows that case that one side (e.g., a rear side) of the second semiconductor chip 100B is bonded with one side (e.g., a front side) of the first semiconductor chip 100A, and FIG. 6 shows the case that the other side (e.g., a front side) of the second semiconductor chip 100B is bonded with one side (e.g., a rear side) of the third semiconductor chip 100C.

Referring to FIG. 6, according to one or more example embodiments, the bonding portion of the second semiconductor chip 100B may include a second semiconductor layer 110b, an interconnection structure 160a, a second connection pad 171b, and a second through electrode 140b. The interconnection structure 160a may include a wiring layer 161b and a wiring insulation layer 162b surrounding the wiring layer 161b.

A bonding portion of the third semiconductor chip 100C may include a third semiconductor layer 110c, a third connection pad 131c, a third insulation layer 132c, and a third through electrode 140c. The third insulation layer 132c may include a lower insulation layer 135c, a first upper insulation layer 134c, and a second upper insulation layer 133c.

Referring to FIG. 6, according to one or more example embodiments, the second connection pad 171b and the third connection pad 131c directly contact each other in the vertical direction, and a wiring insulation layer 162b of the second semiconductor chip 100B may directly contact the lower insulation layer 135c in the vertical direction.

In one or more example embodiments, a width of the second connection pad 171b in the first direction and a width of the third connection pad 131c in the first direction may be different from each other. For example, the width of the second connection pad 171b in the first direction may be smaller than the width of the third connection pad 131c in the first direction. In one or more example embodiments, the width of the second connection pad 171b in the first direction may be substantially the same as the width of first connection pad 131a described with reference to FIG. 2A in the first direction.

In one or more example embodiments, the width of the third through electrode 140c may be greater than a width of the second through electrode 140b. In one or more example embodiments, the width of the third through electrode 140c may be substantially the same as the width of the first through electrode 140a described with reference to FIG. 2A.

The detailed composition of the bonding portion disclosed with reference to FIG. 6 and the effects of the detailed composition are similar to the detailed description of the bonding portion described with reference to FIG. 2A, and therefore a duplicate description will be omitted.

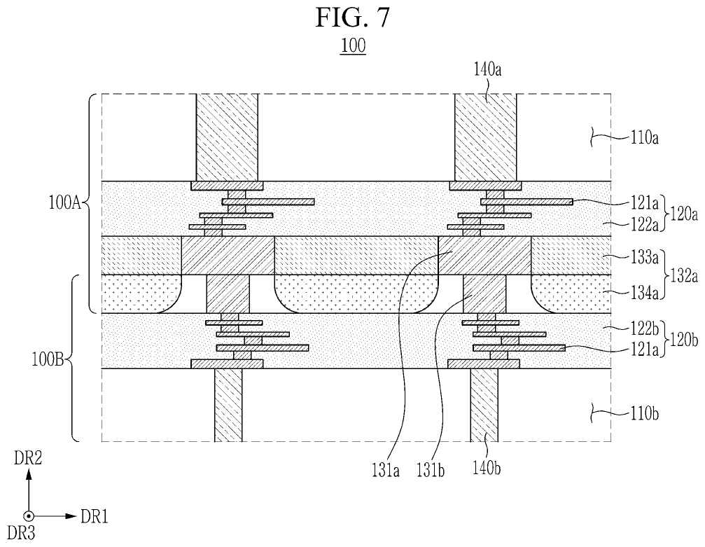

FIG. 7 illustrates a bonding portion of a semiconductor package according to one or more example embodiments.

For example, FIG. 7 may show a bonding portion in a portion where the first semiconductor chip 100A and the second semiconductor chip 100B contact in the semiconductor package of FIG. 1. The bonding portion shown in FIG. 7 may be formed by bonding an upper surface of the first semiconductor chip 100A and an upper surface of the second semiconductor chip 100B.

Referring to FIG. 7, according to one or more example embodiments, the bonding portion of the first semiconductor chip 100A may include a first semiconductor layer 110a, an interconnection structure 120a, a first connection pad 131a, a first insulation layer 132a, and a first through electrode 140a. The interconnection structure 120a may include a wiring layer 121a and a wiring insulation layer 122a surrounding the wiring layer 121a. The first insulation layer 132a may include a lower insulation layer 133a and an upper insulation layer 134a. The bonding portion of the second semiconductor chip 100B may include a second semiconductor layer 110b, a second connection pad 131b, and a second through electrode 140b. The interconnection structure 120b may include a wiring layer 121b and a wiring insulation layer 122b surrounding the wiring layer 121b.

The detailed composition of the bonding portion disclosed with reference to FIG. 7 and the effects of the detailed composition are similar to those of the bonding portion described with reference to FIG. 2A, except that an upper surface of a first semiconductor chip 100A and an upper surface of a second semiconductor chip 100B are bonded to each other, and therefore a duplicate description is omitted.

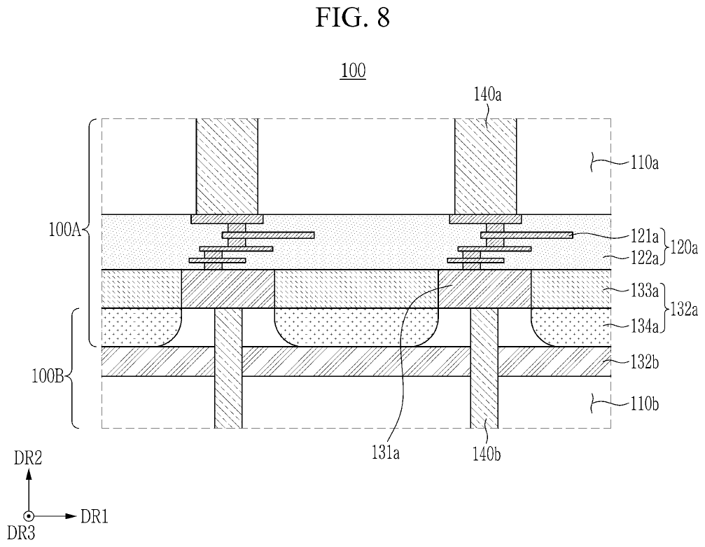

FIG. 8 illustrates a bonding portion of a semiconductor package according to one or more example embodiments.

FIG. 8 may show a bonding portion in a portion where the first semiconductor chip 100A and the second semiconductor chip 100B contact each other in the semiconductor package of FIG. 1. In FIG. 8, the bonding portion may be formed by bonding the upper surface of the first semiconductor chip 100A and the upper surface of the second semiconductor chip 100B.

The second semiconductor chip 100B shown in FIG. 8 may not include a second connection pad on a lower surface thereof. Accordingly, the first connection pad 131a of the first semiconductor chip 100A may directly contact the second through electrode 140b in the vertical direction. In one or more example embodiments, the first connection pad 131a and the second through electrode 140b may include the same metal material. The detailed composition of the bonding portion disclosed with reference to FIG. 8 and the effects of the detailed composition are similar to those of the bonding portion described with reference to FIG. 2A except that the first connection pad 131a of the semiconductor chip 100A directly contacts the second through electrode 140b in the vertical direction, and therefore, a duplicate description is omitted.

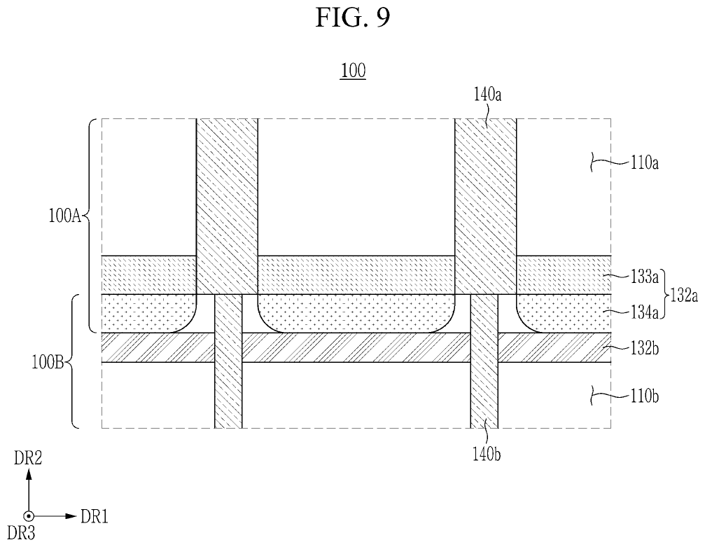

FIG. 9 illustrates a bonding portion of a semiconductor package according to one or more example embodiments.

FIG. 9 may show the bonding portion of a portion where the first semiconductor chip 100A and the second semiconductor chip 100B contact each other in the semiconductor package of FIG. 1. Referring to FIG. 9, according to one or more example embodiments, the first through electrode 140a and the second through electrode 140b may directly contact each other in the vertical direction. In one or more example embodiments, the first through electrode 140a and the second through electrode 140b may include the same metal material.

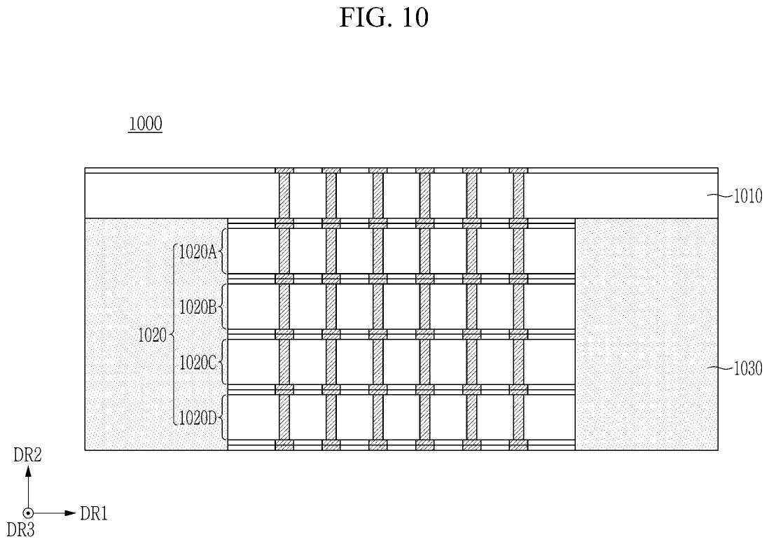

FIG. 10 illustrates a semiconductor package according to one or more example embodiments.

Referring to FIG. 10, according to one or more example embodiments, a semiconductor package 1000 may include a semiconductor chip stacking structure 1020, a top die 1010, and a molding member 1030.

The semiconductor chip stacking structure 1020 may have a structure in which a plurality of semiconductor chips 1020A, 1020B, 1020C, and 1020D are stacked in one direction (e.g., second direction DR2). The top die 1010 may be disposed on the semiconductor chip stacking structure 1020. In one or more example embodiments, the top die 1010 may have a larger width in the first direction DR1 compared to the semiconductor chip stacking structure 1020.

Each of the plurality of semiconductor chips 1020A, 1020B, 1020C, and 1020D stacked on the semiconductor chip stacking structure 1020 may be a memory chip. The top die 1010 may be a buffer die or a logic die. For example, the top die 1010 may be a central processing unit (CPU) chip, a graphic processing unit (GPU) chip, or an application processor (AP) chip.

The semiconductor chip stacking structure 1020 and the top die 1010 may be bonded by hybrid bonding. Each of the semiconductor chips 1020A, 1020B, 1020C, and 1020D included in the semiconductor chip stacking structure 1020 may be bonded to each other by hybrid bonding. Hybrid bonding may be performed by a bonding portion included in each semiconductor chip 1020A, 1020B, 1020C, and 1020D or the top die 1010. The bonding portion may be a portion where the respective semiconductor chips contact each other in the case that the plurality of semiconductor chips 1020A, 1020B, 1020C, and 1020D are stacked and connected. Alternatively, when one of the plurality of semiconductor chips 1020A, 1020B, 1020C, and 1020D and the top die 1010 contact each other, the bonding portion may be a portion where the one of the plurality of semiconductor chips 1020A, 1020B, 1020C, and 1020D and the top die 1010 contact each other.

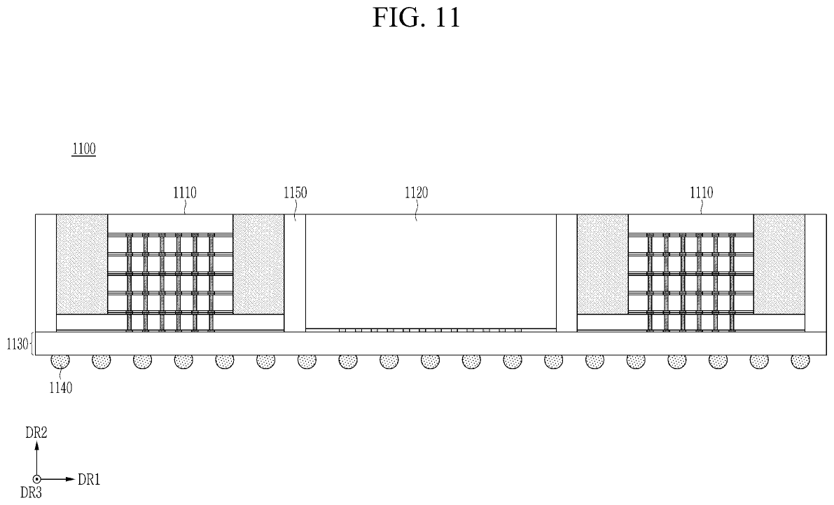

FIG. 11 is a cross-sectional view of a 2.5D semiconductor package including a bonding structure according to one or more example embodiments.

A semiconductor package 1100 of FIG. 11 may include a plurality of first semiconductor chips 1110, a second semiconductor chip 1120, an interposer 1130, and a molding member 1150. The first semiconductor chip 1110 may include the semiconductor stacking structure, the bottom die, and the molding member described with reference to FIG. 1. The second semiconductor chip 1120 may be a logic die.

A substrate may be disposed below the interposer 1130. Connection members may be disposed on a bottom surface of the interposer 1130. In one or more example embodiments, the interposer 1130 may include a silicon interposer.

The first semiconductor chips 1110 and the second semiconductor chip 1120 may be disposed on the interposer 1130. The first semiconductor chips 1110 and the second semiconductor chip 1120 may be bonded with the interposer 1130 by hybrid bonding. The second semiconductor chip 1120 may include connection pads and an insulation layer for hybrid bonding. For hybrid bonding, the contents of hybrid bonding described with reference to FIG. 9 may be applied in a similar way.

The second semiconductor chip 1120 may be disposed side-by-side with the first semiconductor chips 1110 between the first semiconductor chips 1110. In one or more example embodiments, the second semiconductor chip 1120 may include a system on chip (SoC). In one or more example embodiments, the second semiconductor chip 1120 may include a central processing unit (CPU) or a graphic processing unit (GPU).

The molding member 1150 may be disposed on the interposer 1130, and may mold the first semiconductor chips 1110 and the second semiconductor chip 1120. The molding member 240 may serve to protect and insulate the first semiconductor chips 1110 and the second semiconductor chip 1120. In one or more example embodiments, the molding member 240 may be formed of a thermosetting resin such as epoxy resin. In one or more example embodiments, the molding member 240 may comprise an epoxy molding compound (EMC). In one or more example embodiments, the molding process with the molding member 240 may include a compression molding or transfer molding process.

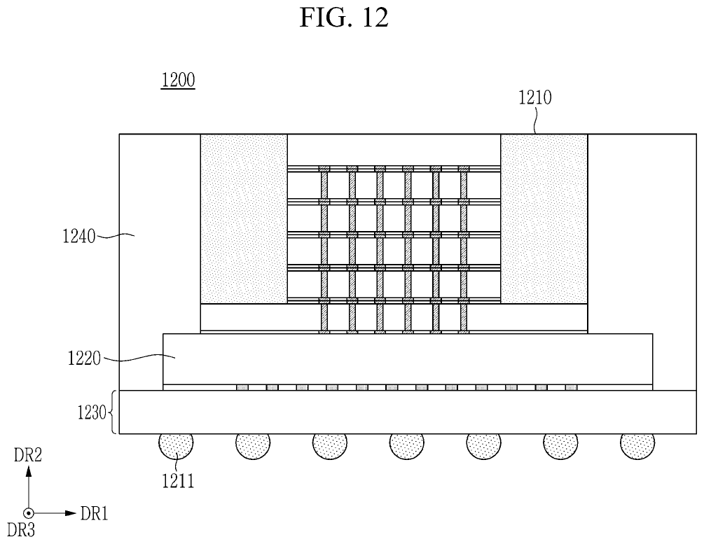

FIG. 12 is a cross-sectional view of a 3D semiconductor package including a bonding structure according to one or more example embodiments.

A semiconductor package 1200 of FIG. 12 may include a first semiconductor chip 1210, a second semiconductor chip 1220, an interposer 1230, and a molding member 1240. The first semiconductor chip 1210 may include the semiconductor stacking structure, the bottom die, and the molding member described with reference to FIG. 1. The second semiconductor chip 1220 may be a logic die.

A substrate may be disposed below the interposer 1230. Connection members may be disposed on a lower surface of the interposer 1230. In one or more example embodiments, the interposer 1230 may include a silicon interposer. The second semiconductor chip 1220 may be disposed on the interposer 1230. The second semiconductor chip 1220 may be bonded with the interposer 1230 by hybrid bonding. For hybrid bonding, the contents of hybrid bonding described with reference to FIG. 9 may be applied in a similar way.

In one or more example embodiments, the second semiconductor chip 1220 may include a system on chip (SoC). In one or more example embodiments, the second semiconductor chip 1220 may include a central processing unit (CPU) or a graphic processing unit (GPU).

The first semiconductor chip 1210 may be disposed on the second semiconductor chip 1220. The first semiconductor chip 1210 may be bonded with the second semiconductor chip 1220 by hybrid bonding. For hybrid bonding, the contents of hybrid bonding described with reference to FIG. 9 may be applied in a similar way.

The molding member 1240 may be disposed on the interposer 1230, and may mold the first semiconductor chips 1210 and the second semiconductor chip 1220. The molding member 1240 may serve to protect and insulate the first semiconductor chips 1210 and the second semiconductor chip 1220. In one or more example embodiments, the molding member 1240 may be formed of a thermosetting resin, such as epoxy resin. In one or more example embodiments, the molding member 240 may comprise an epoxy molding compound (EMC). In one or more example embodiments, the molding process with the molding member 240 may include a compression molding or transfer molding process.

Although one or more example embodiments have been described above, one or more example embodiments are not limited thereto and it will be apparent to those skilled in the art that one or more example embodiments can be modified and implemented in various ways without departing from the spirit and scope of the following claims.

What is claimed is:

1. A semiconductor package comprising:
a first semiconductor chip comprising:
a first semiconductor layer;
a first connection pad provided on a surface of the first semiconductor layer; and
a first insulation layer provided on the surface of the first semiconductor layer, the surface of the first semiconductor layer extending in a first direction; and
a second semiconductor chip comprising:
a second semiconductor layer;
a second connection pad provided on a surface of the second semiconductor layer; and
a second insulation layer provided on the surface of the second semiconductor layer,
wherein the first connection pad directly contacts the second connection pad,
wherein the first connection pad is provided on the second connection pad in a second direction that is perpendicular to the first direction,
wherein the first insulation layer directly contacts the second insulation layer,
wherein the first insulation layer is provided on the second insulation layer in the second direction, and
wherein a width of the second connection pad in the first direction is smaller than a width of the first connection pad in the first direction.

2. The semiconductor package of claim 1, wherein a width of the first insulation layer in the first direction is larger than a width of the second insulation layer in the first direction.

3. The semiconductor package of claim 1, wherein the first connection pad contacts the second connection pad in a first layer,
wherein the first insulation layer contacts the second insulation layer in a second layer, and
wherein a height of the second layer is different from a height of the first layer in the second direction.

4. The semiconductor package of claim 1, wherein the first connection pad extends in the second direction in the first insulation layer,
wherein the first connection pad has a surface provided in a concave portion, and
wherein the second connection pad extends in the second direction in the second insulation layer.

5. The semiconductor package of claim 1, wherein the first connection pad and the first insulation layer are provided on a same layer, and
wherein an empty space is provided between a side surface of the second connection pad and a side surface of the second insulation layer.

6. The semiconductor package of claim 1, wherein a width of the second insulation layer in the first direction decreases as the second insulation layer extends toward a direction opposite to the second direction, and
wherein an edge of a portion of the second insulation layer, adjacent to the second connection pad has a rounded shape.

7. The semiconductor package of claim 1, wherein the first semiconductor chip further comprises a first through electrode that is connected with the first connection pad and penetrates the first semiconductor layer in a direction opposite to the second direction,
wherein the second semiconductor chip further comprises a second through electrode that is connected with the second connection pad and penetrates the second semiconductor layer in the second direction, and
wherein a width of the second through electrode in the first direction is smaller than a width of the first through electrode in the first direction.

8. The semiconductor package of claim 1, wherein the second semiconductor chip comprises a semiconductor device that is provided in a region adjacent to the second connection pad and electrically connected with the second connection pad.

9. The semiconductor package of claim 1, further comprising:
a third semiconductor chip comprising:
a third semiconductor layer;
a third connection pad provided on a surface of the third semiconductor layer; and
a third insulation layer provided on the surface of the third semiconductor layer,
a fourth connection pad directly contacting the third connection pad provided on the third connection pad in the second direction; and
a fourth insulation layer directly contacting the third insulation layer,
wherein a width of the third connection pad in the first direction is larger than a width of the fourth connection pad in the first direction.

10. The semiconductor package of claim 9, wherein the width of the third connection pad in the first direction is the same as a width of the first connection pad in the first direction.

11. The semiconductor package of claim 9, wherein the third semiconductor chip comprises a third through electrode that is connected with the third connection pad and penetrates the third semiconductor layer in the second direction, and
wherein a width of the third through electrode in the first direction is larger than a width of the second through electrode in the first direction.

12. A semiconductor package comprising:
an interposer;
a logic die provided on the interposer; and
a high bandwidth memory provided on the interposer,
wherein the high bandwidth memory comprises:
a buffer die;
a first semiconductor chip that is provided on the buffer die, the first semiconductor chip comprising:
a first semiconductor layer;
a first connection pad provided on a surface of the first semiconductor layer; and
a first insulation layer provided on the surface of the first semiconductor layer, the surface of the first semiconductor layer extending in a first direction; and
a second semiconductor chip comprising:
a second semiconductor layer;
a second connection pad provided on a surface of the second semiconductor layer; and
a second insulation layer provided on the surface of the second semiconductor layer,
wherein the first connection pad directly contacts the second connection pad,
wherein the first connection pad is provided on the second connection pad in a second direction that is perpendicular to the first direction,
wherein the first insulation layer directly contacts the second insulation layer,
wherein the first insulation layer is provided on the second insulation layer in the second direction, and
wherein the semiconductor package comprises a molding member that is provided on the buffer die and molds the first semiconductor chip and the second semiconductor chip.

13. The semiconductor package of claim 12, wherein a width of the first insulation layer in the first direction is larger than a width of the second insulation layer in the first direction.

14. The semiconductor package of claim 12, wherein the first connection pad directly contacts the second connection pad in a first layer,
wherein the first insulation layer contacts the second insulation layer in a second layer, and
wherein a height of the second layer is different from a height of the first layer in the second direction.

15. The semiconductor package of claim 12, wherein a width of the second insulation layer in the first direction decreases as the second insulation layer extends toward a direction opposite to the second direction, and
wherein an edge of a portion of the second insulation layer, adjacent to the second connection pad has a rounded shape.

16. A method of manufacturing a semiconductor package, the method comprising:
forming a first semiconductor chip comprising a first semiconductor layer; a first connection pad, provided on a surface of the first semiconductor layer, and a first insulation layer provided on the surface of the first semiconductor layer, the surface of the first semiconductor layer extending in a first direction;
forming a second semiconductor chip comprising a second semiconductor layer, a second connection pad provided on a surface of the second semiconductor layer, a second insulation layer provided on the surface of the second semiconductor layer; and
bonding the first semiconductor chip and the second semiconductor chip such that the first connection pad and the second connection pad directly contact and the first insulation layer and the second insulation layer directly contact,
wherein a width of the second connection pad in the first direction is smaller than a width of the first connection pad in the first direction.

17. The method of manufacturing the semiconductor package of claim 16, wherein a width of the first insulation layer in the first direction is larger than a width of the second insulation layer in the first direction.

18. The method of manufacturing the semiconductor package of claim 16, wherein the bonding the first semiconductor chip and the second semiconductor chip comprises, after bonding the first connection pad and the second connection pad, annealing the semiconductor package at 160° C. to 220° C.

19. The method of manufacturing the semiconductor package of claim 16, wherein the forming the second semiconductor chip comprises:
forming the second insulation layer including an opening that exposes a surface of the second connection pad on a surface of the second semiconductor chip; and
wet-etching the second insulation layer.

20. The method of manufacturing the semiconductor package of claim 16, wherein the forming the first semiconductor chip comprises forming a first through electrode that is connected with the first connection pad and penetrates the first semiconductor layer in a direction opposite to a second direction that is perpendicular to the first direction,
wherein the forming the second semiconductor chip comprises forming a second through electrode that is connected with the second connection pad and penetrates the second semiconductor layer in the second direction, and
wherein a width of the second through electrode in the first direction is smaller than a width of the first through electrode in the first direction.
